(19) United States
(12) Patent Application Publication
(10) Pub. No.: US 2024/0201233 A1
(43) Pub. Date: Jun. 20, 2024

(54) SUPPLY VOLTAGE MONITORING APPARATUS

(71) Applicant: ZF Automotive UK Limited, Solihull (GB)

(72) Inventors: Naiwu Yuan, Birmingham (GB); Mansoor Shah, Derby (GB)

(21) Appl. No.: 18/526,480

(22) Filed: Dec. 1, 2023

(30) Foreign Application Priority Data
Dec. 14, 2022 (GB) 2218876.7

(51) Int. Cl. G01R 19/165; B60R 16/03

(52) U.S. Cl. CPC G01R 19/16528; B60R 16/03

(57) ABSTRACT

A supply voltage monitoring apparatus for use in an automotive vehicle, having a circuit comprising, an analogue-to-digital converter having an input receiving an analogue voltage signal and an output outputting a digital signal, and an input stage connecting the input of the ADC to the power supply at a point where the value of the link voltage is to be measured. An input stage comprises a potential divider having an upper resistance R1 and a lower resistance R2, the two resistances R1, R2 connected in series two nodes. A first node provides a connection to the link voltage. A second node provides a connection to ground. A centre tap of a potential divider is connected to the input of the ADC. A switchable lower resistance R3 is connected in series with a switch S between the centre tap and the ground, and a control circuit which is arranged to hold the switch S open when the voltage at the centre tap is below a threshold value and to hold the switch closed when the voltage at the centre tap is above the threshold value.

### CROSS-REFERENCE TO RELATED APPLICATION

This application claims priority to German Priority Application No. 2218876.7, filed Dec. 14, 2022, the disclosure of which is incorporated herein by reference in its entirety.

### TECHNICAL FIELD

This disclosure relates to improvements in supply voltage monitoring apparatus for automotive electrical circuits.

### BACKGROUND

In a modern automobile the majority of the core systems such as steering, braking, cruise control, lane assistance and more advanced autonomous driving systems include an electronic circuit that may include various sensors, processing units and actuators such as electric motors. An electric power steering system is an example of a system that once was purely mechanical, for a time relied on hydraulics to reduce the effort needed from a driver to steer a vehicle and which is now almost exclusively electrically assisted. This assistance is provided by an electric motor, which applies a torque to a part of the steering system in response to a torque demand signal from a processing circuit.

The power for these electronic circuits is taken from a battery circuit via a supply rail with the voltage present at the point where power is taken off commonly named the link voltage, Vₗᵢₙₖ. The supply link voltage value depends on a range of factors including the state of charge of the battery, the nominal battery voltage, and the instantaneous power drawn from the battery by the various electrical circuits on the vehicle. It is not uncommon for the voltage Vₗᵢₙₖ to vary from as little as 1.3 volts to a high of 40 volts or more.

To ensure the correct operation of the electrical circuits it is known to provide a voltage monitoring circuit that monitors the voltage Vₗᵢₙₖ. The voltage is converted a digital signal using an analogue to digital conversion stage for onward processing. For a given number of bits output from the ADC, the designer must choose between either high resolution of the output signal for a small range of Vₗᵢₙₖ values, or a low resolution of the output signal for a larger range of Vₗᵢₙₖ values. In the case where a large voltage range is to be observed the resolution of the output signal is therefore poor leading to low accuracy and potentially poor performance.

### SUMMARY

What is needed is to provide a supply voltage monitoring apparatus that ameliorates the problems in the prior art discussed above.

According to a first aspect the disclosure provides a supply voltage monitoring apparatus for use in monitoring the value of a supply voltage Vₗᵢₙₖ of an automotive vehicle, the circuit comprising:

An analogue to digital converter having an input for receiving an analogue voltage signal and an output for outputting a digital signal, and

An input stage which connects the input of the ADC to the power supply at a point where the value of the link voltage Vₗᵢₙₖ is to be measured, the input stage comprising:

A potential divider having an upper resistance R1 and a lower resistance R2, the two resistances R1, R2 connected in series two nodes, a first node providing a connection to the link voltage Vₗᵢₙₖ and a second node providing a connection to ground, the centre tap of the potential divider being connected to the input of the ADC,

A switchable lower resistance R3 which is connected in series with a switch S between the centre tap of the potential divider and the ground, and

A control circuit which is arranged to hold the switch S open to isolate the resistance R3 when the voltage at the centre tap is below a threshold value and to hold the switch closed when the voltage at the centre tap is above the threshold value.

The resistance provided between the centre tap of the main potential divider and ground by R2 alone may be greater than the resistance provided between those two points by R2 and R3 connected in parallel. This ensures that a higher proportion of the value of Vₗᵢₙₖ is dropped across R1 for low values with the switch S open compared to the proportion dropped at high values of Vₗᵢₙₖ where switch S is closed.

By providing for a switchable lower resistance R3 in parallel with the lower resistance R2 when the switch is closed yet isolated from the rest of the circuit when the switch is open the ratio of Vₗᵢₙₖ to Vade can be varied at extremes of high and low values of Vₗᵢₙₖ enabling a higher range of voltages to be measured by the ADC without overloading the input to the ADC and at the same time retaining a high resolution at low voltages compared with a simple arrangement in which Vₗᵢₙₖ or a fixed fraction of Vₗᵢₙₖ is fed direct to the input of an ADC.

The control circuit may include a processing unit which monitors the value of the Vadc signal and when this reaches or is above the threshold value transmits a voltage signal to the switch to cause the switch to turn ON (closed), otherwise not transmitting a signal or a signal too low to turn the switch ON.

Alternatively, the control circuit may comprise a second potential divider comprising a second upper resistance R4 in series with a second lower resistance R5 connected between the centre tap and the ground, the voltage at the centre tap of the second potential divider varying as a function of the Vₗᵢₙₖ voltage and controlling the opening or closing of the switch S. The control circuit may therefore be completely passive components.

The switch may comprise a MOSFET or other transistor and the gate or base of the transistor may be supplied with the voltage signal output at the centre tap of the second potential divider or from the microprocessor.

The input stage may be arranged such that a Vₗᵢₙₖ voltage varying from around 6 volt to around 40 volts generates an input voltage for the ADC that varies from around 1.3 volts to around 5 volts.

Where a potential divider is provided to apply the voltage signal to the gate of the switch the value of R4 plus R5 may be chosen such that they are at least 10 times, and in one exemplary arrangement, at least 100 times, greater than the values of R2 or R3 so that the voltage present at the input to the ADC is approximately defined by the following equation when the switch is OFF (open so that no current can flow through the switch):

$${V}_{adc} = {V}_{link} \frac{R 2}{R 1 + R 2}$$

And for when the switch is ON (closed to allow current to flow through it) the voltage present at the input to the ADC is given by the equation:

$${V}_{adc} = {V}_{link} \frac{{R}_{parallel}}{R 1 + {R}_{parallel}}$$

$$where$$

$${R}_{parallel} = \frac{R 2 * ( R 3 + Rdson )}{R 2 + R 3 + R dson}$$

Where Rdson is the ON resistance of the switch, for example the resistance between source and drain of a MOSFET that has been turned ON.

The supply voltage monitoring circuit may include a processing unit which receives the digital signal output from the ADC and maps the digital signal to a value for the Vₗᵢₙₖ voltage. This may be the same processing unit that triggers the switch where that arrangement is used.

The processing circuit may include an algorithm that performs the mapping, or alternatively a look up table may be provided that uses the value of the digital signal as an index to a table in which Vₗᵢₙₖ voltage values are stored.

### BRIEF DESCRIPTION OF DRAWINGS

There will now be described by way of example only one exemplary arrangement of the present disclosure with reference to the accompanying of which:

FIG. 1 is an overview of a supply voltage monitoring apparatus fitted to a vehicle electrical power circuit;

FIG. 2 is a detailed circuit diagram showing the components of an input circuit of the supply voltage monitoring apparatus of FIG. 1; and

FIG. 3 shows the relationship between the Vₗᵢₙₖ voltage and the input voltage to the ADC along with the threshold at which the switch S is opened or closed; and

FIG. 4 is a detailed circuit diagram showing the components of a second exemplary arrangement of an input circuit of the supply voltage monitoring apparatus of FIG. 1.

### DETAILED DESCRIPTION

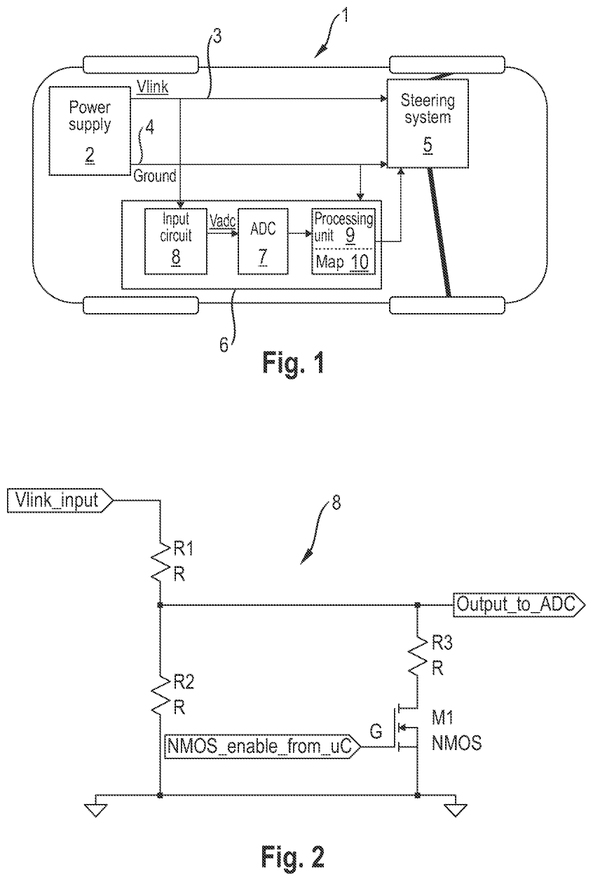

In FIG. 1, a vehicle 1 includes a power supply 2 in the form of a battery. This battery is connected to a voltage supply rail 3 and earthed 4 to the chassis of the vehicle. At a point along the supply rail an electrical cable is connected which terminates at a convenient location on the vehicle at a power take off. The supply voltage at this take off has a value Vₗᵢₙₖ that can vary in use of the vehicle. For the sake of an example, it is assumed this varies from a low of 6 volts to a high of 40 volts.

The take off provides a convenient point from which an automotive electrical sub-assembly can take power. An example of such an assembly is an electrical power steering assembly 5. The assembly 5 is also connected to the vehicle chassis and hence the ground 4 of the battery.

A supply voltage monitoring apparatus 6 is provided for monitoring the value of the supply voltage Vₗᵢₙₖ. This may then be fed to a processing circuit of the sub-assembly 5, for example to allow for the effects of a varying Vₗᵢₙₖ voltage to be taken into consideration when operating the sub-assembly. In the case of a steering assembly a low measured value of Vₗᵢₙₖ may indicate that only a limited torque can be applied by an electric motor to assist a driver. The value of the Vₗᵢₙₖ signal is also commonly used in fault diagnostics as in indicator that the sub-assembly is receiving power as expected.

The supply voltage monitoring apparatus 6 comprises an analogue to digital converter ADC 7 having an input for receiving an analogue voltage signal and an output for outputting a digital signal. The monitoring apparatus further includes an input stage 8 which receives the Vₗᵢₙₖ voltage that is to be measured and feeds this to an input of the ADC. This also includes an optional processing unit 9 that maps the output of the ADC to a value for the Vₗᵢₙₖ voltage.

The input stage 8 comprises a network of passive components, and can be configured using a small number of resistors and a single switch as shown in FIG. 2. Note that each resistance can be made up of a single resistor or a network of resistors arranged in series or parallel.

The resistors are connected to form a potential divider having an upper resistance R1 and a lower resistance R2, the two resistances R1,R2 connected in series between the Vₗᵢₙₖ and a ground. The path connecting the two resistors defines a centre tap of the potential divider and this is connected directly to the input of the ADC.

A switchable lower resistance R3 is also connected in series with a switch S between the centre tap of the potential divider and the ground. When the switch is open (OFF) the resistance R3 is isolated from the rest of the circuit. When the switch is closed (ON) the resistance R3 is connected in parallel with the resistance R2. This alters the value of the lower resistance of the potential divider as the switch is opened and closed, changing the ratio between the Vₗᵢₙₖ voltage and the voltage presented to the input of the ADC.

The switch is opened and closed in response to a voltage signal that is supplied from a processing unit. The value of this signal is held at or close to zero volts when the value of the link voltage is below a threshold and to a high voltage, for example 6 volts or more, when the link voltage exceeds the threshold. The switch S is a MOSFET with the gate of the MOSFET connected to this voltage signal.

The switch is open (OFF) at link voltages below the threshold. When the link voltage is above the threshold value the signal voltage applied is above the gate voltage required to turn on the MOSFET the switch S closes (ON) and the resistance R3 plus the turn on voltage Rdson of the MOSFET is placed in parallel with the resistance R2. The bottom resistance of the first potential divider is now smaller since it is defined by R2 and R3+Rdson rather than R2 alone.

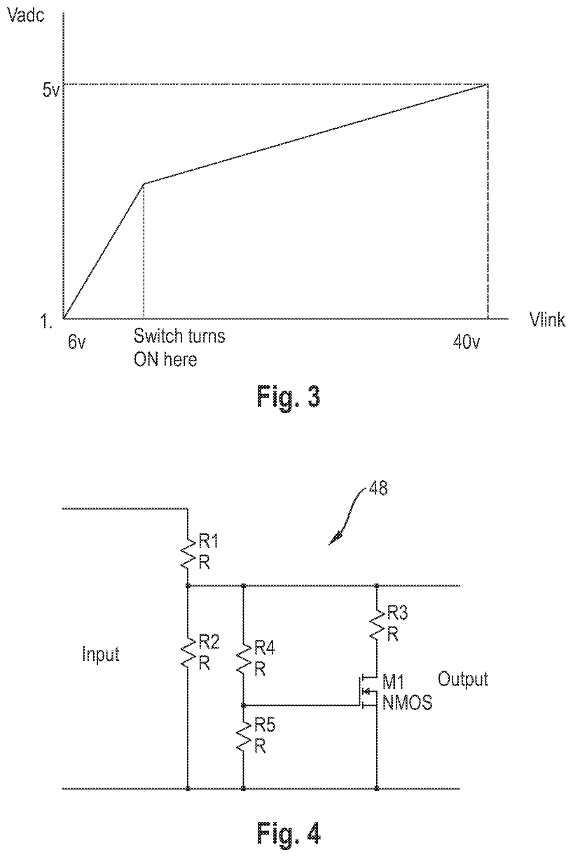

FIG. 3 shows how the voltage at the input to the ADC varies as a function of the voltage Vₗᵢₙₖ. The value of Vₗᵢₙₖ at which the signal is fed to the gate of the switch that closes the switch is marked by the vertical dotted line. The ratio of Vₗᵢₙₖ/V_{adc} is different either side of this threshold, with a larger change in the voltage at the ADC occurring for a given change in input voltage at the low end compared with that at the higher Vₗᵢₙₖ voltages.

An alternative arrangement of an input stage 48 is shown in FIG. 4. In this arrangement the voltage signal fed to the gate of the switch S is supplied from a further potential divider.

The components R1, R2, R3 and the switch are all the same as used in the first arrangement and are interconnected in essentially the same way and according have been indicted using like reference numerals for clarity.

The switch S is opened and closed using a simple pair of resistances R4 and R5 that form a control circuit for the switch. The switch S is a MOSFET with the gate of the MOSFET connected to the centre tap of the second potential divider between R4 and R5. The sum of the values of R4 and R5 are chosen to be significantly greater than the values of R2 and R3.

The switch is open (OFF) at low input voltages that place the voltage at the centre tap of the second potential divider below the turn on voltage of the MOSFET. With the switch open, R3 is isolated. When the voltage at the centre tap is above a threshold value corresponding to the turn on voltage of the MOSFET the switch S closes (turns ON) and the resistance R3 is placed in parallel with the resistance R2. The bottom resistance of the first potential divider is now smaller since it is defined by R2 and R3 rather than R2 alone. Since the resistance between source and drain is a function of the gate-source voltage, and both of these voltages are influenced as the switch starts to turn ON, the transition from OFF to ON is not instance but will occur gradually until the switch is fully turned ON. During this phase the rate of change of V_{ADC} for a given change of Vₗᵢₙₖ will be reduced as shown in FIG. 3 starting at the dotted line which corresponds to the MOSFET starting to turn ON.

The voltage input to the ADC generates a digital output signal from the ADC. This is fed to the processing unit that maps the value of the digital signal to a value of Vₗᵢₙₖ, taking account the non-linearity of the digital signal over the full range of the Vₗᵢₙₖ values that are measurable without overloading the ADC.

The values of the resistances used should be chosen as a function of the desired range of voltages Vₗᵢₙₖ that are to be measured by the ADC and of the turn on voltage of the switch. The skilled person familiar with electronic circuit design will understand how to chose optimal values taking account the gate turn on voltage of the MOSFET, the value of Rdson

1. A supply voltage monitoring apparatus for use in monitoring a value of a supply voltage of an automotive vehicle, a circuit comprising:
An analogue to digital converter (ADC) having an input for receiving an analogue voltage signal and an output for outputting a digital signal, and
An input stage which connects the input of the ADC to a power supply at a point where the value of the supply voltage Vₗᵢₙₖ is to be measured, the input stage comprising:
a potential divider having an upper resistance and a lower resistance, the two resistances connected in series to two nodes, a first node providing a connection to the supply voltage and a second node providing a connection to ground, the centre tap of the potential divider being connected to the input of the ADC,
a switchable lower resistance which is connected in series with a switch between the centre tap of the potential divider and the ground, and
a control circuit which is arranged to hold the switch open when the voltage at the centre tap is below a threshold value and to hold the switch closed when the voltage at the centre tap is above the threshold value.

2. A supply voltage monitoring apparatus according to claim 1 in which the control circuit includes a processing unit which monitors a value of the output signal and when the output signal reaches or is above the threshold value transmits a voltage signal to the switch to hold the switch closed (ON).

3. A supply voltage monitoring apparatus according to claim 1 in which the control circuit comprises a second potential divider comprising a second upper resistance in series with a second lower resistance connected between the centre tap and the ground, a voltage at the centre tap of the second potential divider varying as a function of the supply voltage and controlling the opening or closing of the switch.

4. A supply voltage monitoring apparatus according to claim 2 in which the switch comprises a MOSFET transistor and a gate of the transistor is supplied with the voltage signal.

5. A supply voltage monitoring apparatus according claim 1, further comprising a processing unit which receives the digital signal output from the ADC and maps the digital signal to a value for the supply voltage.

6. A supply voltage monitoring apparatus according to claim 3 in which the switch comprises a MOSFET transistor and a gate of the transistor is supplied with the voltage signal.

7. A supply voltage monitoring apparatus according claim 3, further comprising a processing unit which receives the digital signal output from the ADC and maps the digital signal to a value for the supply voltage.

8. A supply voltage monitoring apparatus according claim 4, further comprising a processing unit which receives the digital signal output from the ADC and maps the digital signal to a value for the supply voltage.

9. A supply voltage monitoring apparatus according claim 6, further comprising a processing unit which receives the digital signal output from the ADC and maps the digital signal to a value for the supply voltage.
